(19) United States
(12) Patent Application Publication
(10) Pub. No.: US 2014/0246774 A1
(43) Pub. Date: Sep. 4, 2014

(54) SEMICONDUCTOR DEVICE HAVING A BUFFER LAYER AND METHOD OF MANUFACTURING THE SAME

(71) Applicant: DONGBU HITEK CO., LTD., Seoul (KR)

(72) Inventor: Nam Gon CHOI, Seoul (KR)

(73) Assignee: DONGBU HITEK CO., LTD., Seoul (KR)

(21) Appl. No.: 13/832,038

(22) Filed: Mar. 15, 2013

(30) Foreign Application Priority Data
Mar. 4, 2013 (KR) 10-2013-0023053

(51) Int. Cl. H01L 23/498; H01L 21/50

(52) U.S. Cl. CPC H01L 23/49816; H01L 21/50
USPC 257/738; 438/121

(57) ABSTRACT

A semiconductor device and method for manufacturing the same are provided. A metal pad can be electrically connected to metal interconnections in a lower portion of the device. A passivation layer can be provided and can exposes a portion of the metal pad, and a buffer layer can be formed on lateral sides of the passivation layer.

### CROSS-REFERENCE TO RELATED APPLICATION

This application claims the benefit under 35 U.S.C. §119 of Korean Patent Application No. 10-2013-0023053, filed Mar. 4, 2013, which is hereby incorporated by reference in its entirety.

### BACKGROUND

Currently, many consumers prefer products that are smatter, convenient to carry, and multifunctional, such a mobile phones, notebook computers, and digital cameras, which are made smaller, convenient to carry, and multifunctional, becomes higher. Such products continue to evolve in a direction of requiring a large capacity storage device and high speed signal processing, as well as miniaturization.

As the operation speed and the capacity of a chip increases, packages having a structure in which a multi-layered semiconductor chip is contained in a single package become commonly used. As a scheme of manufacturing a multi-layered chip, there are two schemes such as wafer level packaging and chip level packaging.

Typically, two or more different wafers in a wafer state are bonded to each other, in order to be electrically connected to each other, and then a single chip is manufactured by cutting the bonded one by an individual chip unit. This is referred to as wafer level packaging. For a high speed and large capacity chip, the wafer level packaging is generally preferred, in part because it has a low number of times of bonding and is advantageous in reducing the packaging time and cost compared to chip level packaging.

In a related art wafer level packaging process, due to an external impact such as a solder ball drop and thermal processing, a metal pad and a passivation layer may be separated from an interface of an interlayer dielectric, that is formed under the metal pad and the passivation layer, and cracks may occur under the passivation layer.

FIGS. 1A to 1C are cross-sectional views showing a related art packaging process for manufacturing a semiconductor device.

Referring to FIG. 1A, interlayer dielectrics 14, 16, 18, and 20 are formed on a semiconductor substrate (not shown), and metal pads 32 and contacts 30 connecting the respective metal pads 32 are formed in each of the interlayer dielectrics 14, 16, 18, and 20. A metal pad 34 is formed on an upper portion of the interlayer dielectric 20. Thereafter, a passivation layer 40 is formed by sequentially stacking an oxide film 42 and a nitride film 44 on a whole surface of an upper portion of the interlayer dielectric 20.

Referring to FIGS. 1B and 1C, the passivation layer 40 is patterned to expose the metal pad 34, and then sintering is performed thereon.

In a packaging process after the sintering, a solder ball 36 like gold (Au) having a high specific gravity may be dropped on a surface of the exposed metal pad 34. At this time, due to an external pressure or impact when the solder ball 36 is dropped, and heat created at the time of wire bonding, there are limitations that the passivation layer 40 and the metal pad 34 may be separated from the interlayer dielectric 20, or cracks may occur under the metal pad 34 or the passivation layer 40.

### BRIEF SUMMARY

Embodiments of the subject invention provide a semiconductor device and method of manufacturing the same. A semiconductor device according to embodiments of the subject invention can inhibit cracks from being created in a passivation layer and a metal layer, as well as inhibit the passivation layer from being separated from an interlayer dielectric in subsequent processes, by forming oxide film patterns of a side wall shape on lateral sides of the passivation layer.

In an embodiment, a semiconductor device can include: a metal pad electrically connected to metal interconnections in a lower portion of the semiconductor device; a passivation layer exposing a portion of the metal pad; and a buffer layer formed on lateral sides of the passivation layer.

In another embodiment, a method of manufacturing a semiconductor device can include: forming a metal pad on an interlayer dielectric and connected to metal interconnections in a lower portion of the semiconductor device; forming a passivation layer on the metal pad and exposing an upper portion of the metal pad; and forming a buffer layer on lateral sides of the passivation layer.

### BRIEF DESCRIPTION OF THE DRAWINGS

FIGS. 1A to 1C are cross-sectional views illustrating a related art process of manufacturing a semiconductor device.

FIG. 2A is a cross-sectional view of a semiconductor device according to an embodiment of the subject invention.

FIG. 2B is a plan view of a semiconductor device according to an embodiment of the subject invention.

FIG. 3A to 3E are cross-sectional views showing a method of manufacturing a semiconductor device according to an embodiment of the subject invention.

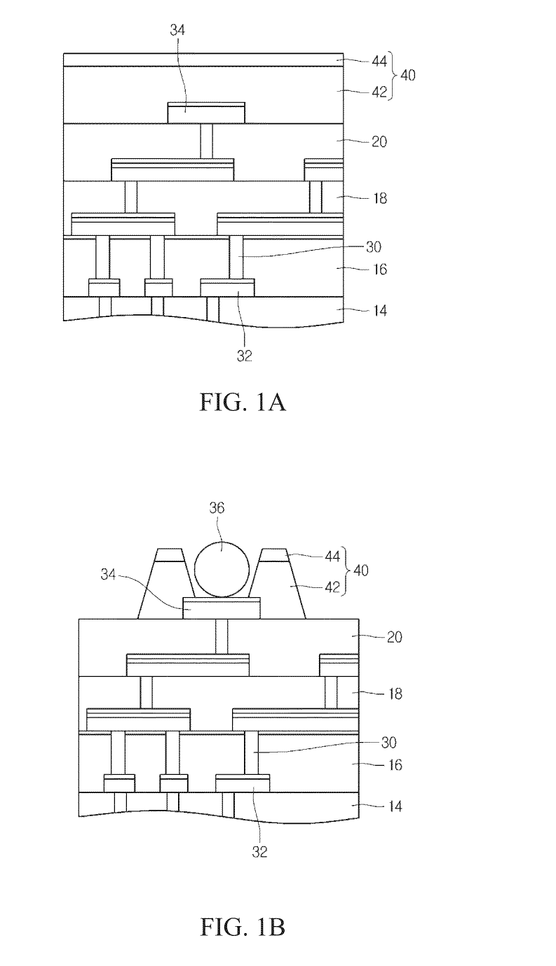

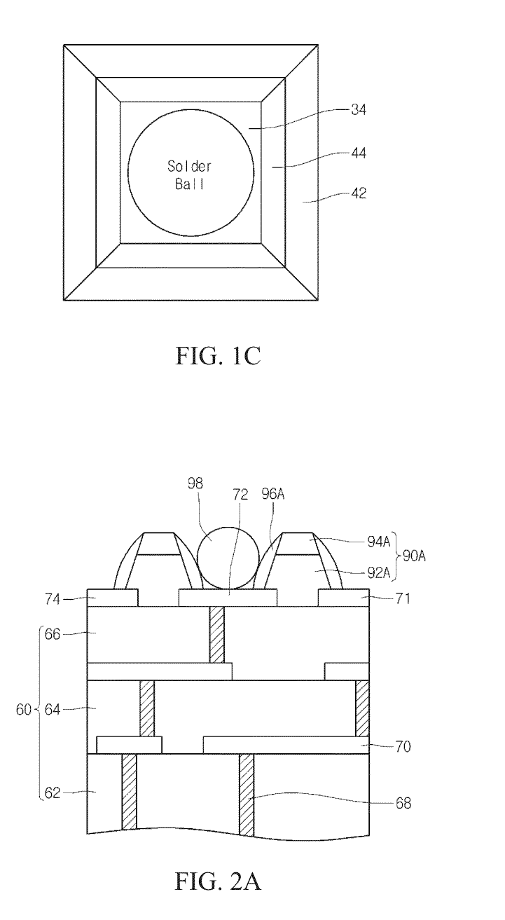

### DETAILED DESCRIPTION

Reference will now be made in detail to the embodiments of the present disclosure, examples of which are illustrated in the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

A semiconductor device can be manufactured by performing processes of photolithography, etching, ion injection, and diffusion to form a plurality of chips, and applying a packaging process to each of the chips. The packaging process is a process of connecting a pad connected to an external circuit to a lead line, and sealing the chip with a plastic chip carrier. Prior to performing the packaging process, a pad opening process for exposing the pad can be performed. The pad formed of a conductive material can be protected from surroundings by a protection film formed thereon. The protection film can be, for example, a silicon oxide film, a silicon nitride film, or a combination thereof. In the pad opening process, the protection film can be partially etched and removed, and then the pad can be exposed. Embodiments of the subject invention provide means for protecting a passivation layer formed of a silicon oxide film and a silicon nitride film in the pad opening process before performing the packaging process.

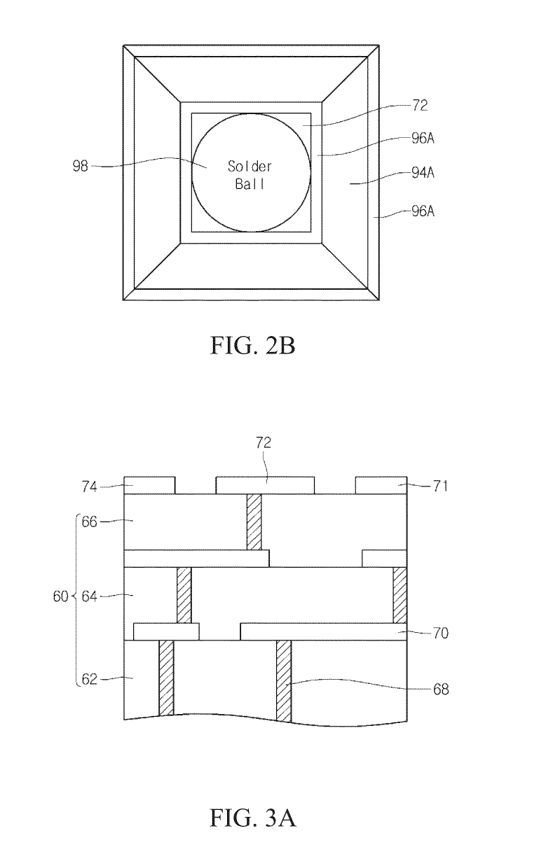

FIG. 2A is a cross-sectional view of a semiconductor device according to an embodiment of the subject invention.

Referring to FIG. 2A, in an embodiment, multiple interlayer dielectrics 62, 64, and 66 can be formed on a semiconductor substrate (not shown). Though three interlayer dielectrics are shown, embodiments are not limited thereto. Any reasonable number of interlayer dielectrics can be formed. In each of the interlayer dielectrics 62, 64, and 66, metal interconnections 68 connecting each metal pad 70 can be formed. A structure of the interlayer dielectrics 62, 64, and 66, metal pads 70, and metal interconnections 68 is shown by way of example only, and embodiments of the subject invention may be applied to any structure including a semiconductor device where the packaging process is performed.

Upper side metal pads 71, 72, and 74 can be formed on an upper side of the interlayer dielectric 66 disposed on the uppermost portion of the semiconductor device. A passivation layer 90A can be formed. In an embodiment, the passivation layer 90A can include an oxide film pattern 92A and a nitride film pattern 94A. Such a passivation layer 90A can be formed by stacking an oxide film and a nitride film (not necessarily in that order) and then patterning the films. The passivation layer 90A can be patterned to expose the upper metal pads 71, 72, and 74, and/or formed in a structure where the oxide film and the nitride film are stacked, but is not limited thereto.

Buffer layers 96A can be formed on lateral sides of the passivation layer 90A. The buffer layers 96A can be patterned in a side wall shape on the side walls of the passivation layer 90A, and can play a role of a buffer which distributes stress due to an external pressure and an impact applied when a solder ball 98 lands on the metal pad 72.

FIG. 2B is a plan view of a semiconductor device according to an embodiment of the subject invention.

Referring to FIG. 2B, a buffer layer 96A can be formed to enclose a solder ball 98, when viewed from above, after the solder ball 98 lands during the packaging process. Since the solder ball 98 first contacts the buffer layer 96A when landing on the upper metal pad 72, the passivation layer 90A can be protected, and an impact to the metal pad 72 can be alleviated.

Hereinafter, a method of manufacturing a semiconductor device will be described with the accompanying drawing.

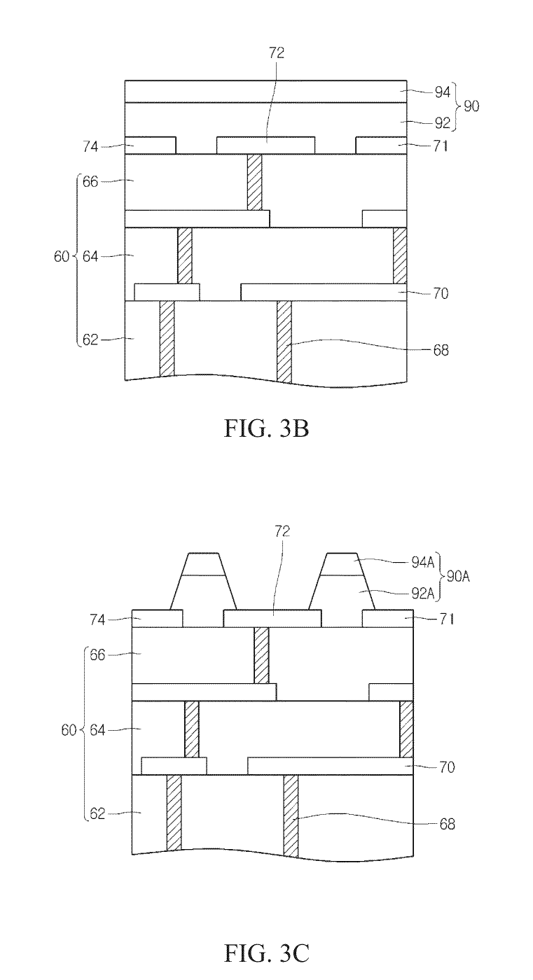

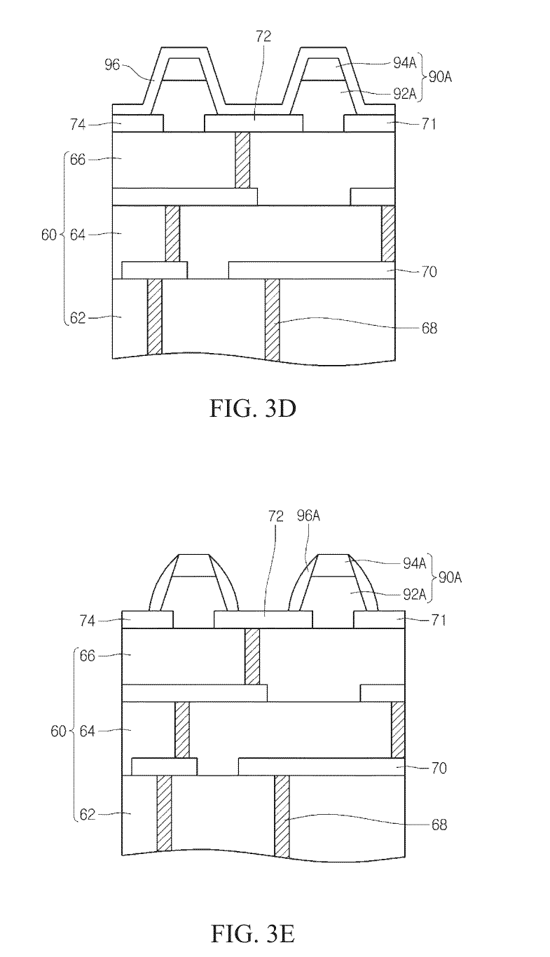

FIGS. 3A to 3E are cross-sectional views of a method of manufacturing a semiconductor device according to an embodiment of the subject invention.

Referring to FIG. 3A, interlayer dielectrics 62, 64, and 66 are formed on a semiconductor substrate (not shown), and metal pads 70 and metal interconnections 68 connecting respective metal pads 70 to each other are formed in each of the interlayer dielectrics 62, 64, and 66. Though three interlayer dielectrics are shown, embodiments are not limited thereto. Any reasonable number of interlayer dielectrics can be formed. A structure where the metal pads 70 and the metal interconnections 68 are formed in the interlayer dielectrics 62, 64, and 66 is shown by way of example only, and embodiments of the subject invention may be applied to all structures including a semiconductor device.

A metal material can be sputtered on an upper portion of the interlayer dielectric 66, and the sputtered metal material can be patterned to form the metal pads 71, 72, and 74 on the upper portion of the interlayer dielectric 66.

Referring to FIG. 3B, in an embodiment, an oxide film 92 and a nitride film 94 can be sequentially stacked on upper portions of the metal pads 71, 72, and 74, to form a passivation layer 90. Though a passivation layer 90 formed of an oxide film 92 and a nitride film 94 is shown, embodiments are not limited thereto. For example, the passivation layer 90 may include other materials, just an oxide film 92, just a nitride film 94, or some combination thereof, (e.g., another oxide film can be formed on an upper portion of the nitride film 94).

Referring to FIG. 3C, the passivation layer 90 can be patterned to expose the metal pads 71, 72, and 74.

Thereafter, referring to FIG. 3D, a buffer film 96 having a predetermined thickness can be formed on the entire surface of an upper portion of the patterned passivation layer 90A. The buffer film 96 can be formed of, for example, an oxide film, though embodiments are not limited thereto. In an embodiment, the buffer film 96 can be formed by thermal oxidation.

Referring FIG. 3E, etching (e.g., isotropic etching) can performed on the buffer film 96. Buffer layers 96A can be formed in a side wall shape on the lateral sides of the passivation layer 90A by the etching (e.g., isotropic etching). The buffer layers 96A, formed on the lateral sides of the passivation layer 90A in a predetermined thickness, can play a support role, which inhibits the passivation layer 90A in a region where a line width is narrow from being damaged or destroyed.

Thereafter, a packaging process for attaching a solder ball 98 can be performed on an upper portion of the exposed metal pads 71, 72, and 74 interposed between the patterned passivation layers 90A. In the process of attaching the solder ball 98, the solder ball 98 can be attached by landing on the buffer layers 96A formed on the lateral sides of the passivation layers 90A. Referring again to FIG. 2B, because the buffer layers 96A are formed to enclose the solder ball 98, the solder ball 98 initially contacts the buffer layers 96A and is then attached to the metal pad 72.

That is, four points of the spherical solder ball 98 can be supported by the buffer layers 96A, thereby reducing stress added to the metal pad 72 and the passivation layer 90A in the attachment process.

As described herein, according to the method of manufacturing a semiconductor device of the embodiment, buffer layers 96A can be formed on the lateral sides of a patterned passivation layer 90A. Accordingly, the buffer layer 96A can inhibit damage of the passivation layer 90A which may be caused by an impact at the time of solder ball attachment or a wafer transfer in the packaging process.

The buffer layers 96A, formed on the lateral sides of the passivation layer 90A, can provide support and thereby inhibit the passivation layer 90A in a region where a line width is narrow from being damaged or destroyed. The buffer layers 96A can also improve a limitation that a chip size typically becomes increased due to reservation of an unnecessary margin in a semiconductor chip. That is, the buffer layers 96A can lead to smaller chip sizes.

A semiconductor device and a method of manufacturing the same according to embodiments of the subject invention can inhibit damages in a passivation layer and a metal layer due to impacts which may occur in a packaging process or at the time of wafer transfer. One or more buffer layers can be formed on lateral side walls of a passivation layer in order to alleviate an impact of a solder ball.

Any reference in this specification to “one embodiment”, “an embodiment”, “example embodiment”, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A semiconductor device, comprising:
a metal pad electrically connected to metal interconnections in a lower portion of the semiconductor device;
a passivation layer exposing a portion of the metal pad wherein the passivation layer is formed in a step shape with oblique lateral sides; and
a buffer layer formed on the lateral sides of the passivation layer.

2. The semiconductor device according to claim 1, wherein the passivation layer comprises an oxide film and a nitride film.

3. The semiconductor device according to claim 1, wherein the buffer layer is formed by an isotropic etching process.

4. The semiconductor device according to claim 1, wherein the buffer layer comprises an oxide film.

5. The semiconductor device according to claim 1, further comprising a solder ball disposed on the metal pad and in contact with the buffer layer.

6. The semiconductor device according to claim 5, wherein the buffer layer is configured such that, when the solder ball is initially disposed on the metal pad, the solder ball contacts the buffer layer before the solder ball contacts the metal pad.

7. The semiconductor device according to claim 5, wherein the passivation layer with the buffer layer on its lateral sides provides a lateral barrier to contain the solder ball.

8. The semiconductor device according to claim 1, wherein the buffer layer is provided on all lateral sides of the passivation layer.

9. A method of manufacturing a semiconductor device, the method comprising:
forming a metal pad on an interlayer dielectric and connected to metal interconnections in a lower portion of the semiconductor device;
forming a passivation layer on the metal pad and exposing an upper portion of the metal pad wherein the passivation layer is formed in a step shape with oblique lateral sides; and
forming a buffer layer on the lateral sides of the passivation layer.

10. The method according to claim 9, wherein forming the passivation layer comprises;
stacking an oxide film on the interlayer dielectric;
stacking a nitride film on the oxide film; and
patterning the oxide film and the nitride film to expose a portion of the metal pad.

11. The method according to claim 9, wherein forming the buffer layer comprises,
forming an oxide film on the entire surface of the passivation layer; and
performing an isotropic etch on the oxide film.

12. The method according to claim 9, wherein the passivation layer comprises an oxide film, a nitride film, or both.

13. The method according to claim 9, further comprising disposing a solder ball on the exposed metal pad.

14. The method according to claim 13, wherein disposing the solder ball on the exposed metal pad comprises:
contacting the solder ball to the buffer layer; and
after contacting the solder ball to the buffer layer, contacting the solder ball to the metal pad.

15. The method according to claim 13, wherein the passivation layer with the buffer layer on its lateral sides provides a lateral barrier to contain the solder ball.

16. The method according to claim 9, wherein forming the buffer layer on lateral sides of the passivation layer comprises forming the buffer layer on all lateral sides of the passivation layer.
